(19) United States
(12) Patent Application Publication
(10) Pub. No.: US 2017/0040140 A1
(43) Pub. Date: Feb. 9, 2017

(54) MAGNET ARRAY FOR PLASMA-ENHANCED CHEMICAL VAPOR DEPOSITION

(71) Applicant: Seagate Technology LLC, Cupertino, CA (US)

(72) Inventors: Samuel L. Tanaka, Fremont, CA (US); Christopher L. Platt, Fremont, CA (US); Thomas L. Greenberg, Berkeley, CA (US)

(21) Appl. No.: 14/820,160

(22) Filed: Aug. 6, 2015

(51) Int. Cl. H01J 37/07; H01J 37/02; G11B 5/85; C23C 16/50

(52) U.S. Cl. CPC H01J 37/07; C23C 16/50; H01J 37/023; G11B 5/85; H01J 2237/3321

(57) ABSTRACT

Provided herein is an apparatus comprising a deposition chamber with a cathode, and a means for creating an asymmetric field about the cathode.

### BACKGROUND

A hard disk drive (HDD) includes magnetic recording media (e.g. one or more disks) for storing digital data. Magnetic recording media may include multiple thin film layers deposited on a substrate. One or more of the thin film layers may be deposited using plasma-enhanced chemical vapor deposition (PECVD). Current PECVD processes may use a hot filament electron source to deposit thin film layers onto a substrate. As the filament ages, gravity may pull the filament downwards, creating an uneven deposition with a thicker deposit towards the bottom of the substrate and a thinner deposition towards the top of the substrate.

### SUMMARY

Provided herein is an apparatus comprising a deposition chamber with a cathode, and a means for creating an asymmetric field about the cathode.

These and other features and/or aspects of the concepts provided herein may be better understood with reference to the following drawings, description, and appended claims.

### BRIEF DESCRIPTION OF THE DRAWINGS

FIG. 1 illustrates a PECVD apparatus with integrated magnet array components according to one aspect of the present description.

FIG. 2 illustrates PECVD apparatus components according to one aspect of the present description.

FIG. 3A illustrates a magnet array according to one aspect of the present description.

FIG. 3B illustrates a magnet array according to one aspect of the present description.

FIG. 3C illustrates a cross-sectional view of a magnet array according to one aspect of the present description.

FIG. 4 illustrates a magnet array rotation according to one aspect of the present description.

FIG. 5 illustrates a PECVD apparatus with an integrated magnet array according to one aspect of the present description.

FIG. 6 illustrates a graphical comparison of static and rotating range percentages of substrate sides according to one aspect of the present description.

### DETAILED DESCRIPTION

Before some particular embodiments are illustrated and/or described in greater detail, it should be understood that the particular embodiments do not limit the scope of the concepts provided herein, as features of such particular embodiments may vary. It should likewise be understood that a particular embodiment has features that may be readily separated from the particular embodiment and optionally combined with or substituted for features of any of a number of other embodiments illustrated and/or provided herein.

It should be noted that the descriptions that follow, for example, in terms of a PECVD apparatus are described for illustrative purposes only and the underlying system can apply to any number and multiple types of material deposition processes.

It should be understood that the terminology used herein is for the purpose of describing some particular embodiments, and the terminology does not limit the scope of the concepts provided herein. Unless indicated otherwise, ordinal numbers (e.g., first, second, third, etc.) are used to distinguish or identify different features or steps in a group of features or steps, and do no supply a serial or numerical limitation. For example, “first,” “second,” and “third” features or steps need not necessarily appear in that order, and the particular embodiments need not necessarily be limited to the three features or steps. It should also be understood that, unless indicated otherwise, any labels such as “left,” “right,” “front,” “back,” “top,” “bottom,” “forward,” “reverse,” “clockwise,” “counter clock-wise,” “up,” “down,” or other similar terms such as “upper,” “lower,” “aft,” “fore,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Unless defined otherwise, all technical and scientific terms used herein have the same meaning as commonly understood by persons of ordinary skill in the art.

### General Overview

One challenge in HDD manufacturing is reducing deposition-related defects in the substrate. Specifically with PECVD, a hot filament electron source may be used to deposit thin film layers onto a substrate. However, as the filament ages, gravity may pull the filament down, creating an asymmetric electron distribution. As a result, there may be a higher plasma density low in the source, which may lead to a thicker deposit towards the bottom of the substrate. Since replacing the filament requires shutting down the PECVD process for a length of time, finding a way of compensating for the sagging filament without extensive downtime is desirable. Provided herein is an apparatus for a magnet array configured to increase PECVD uniformity by asymmetrically affecting the plasma distribution.

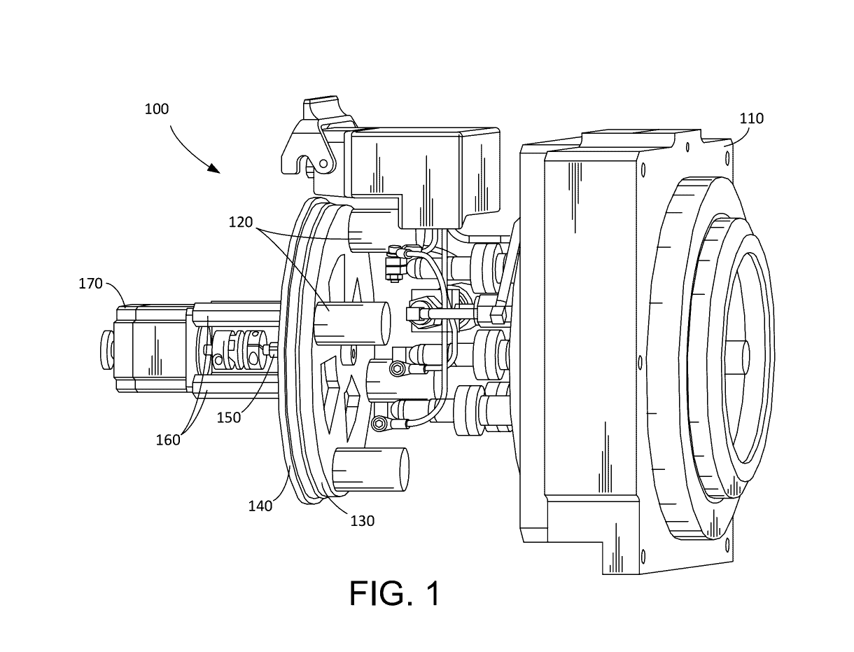

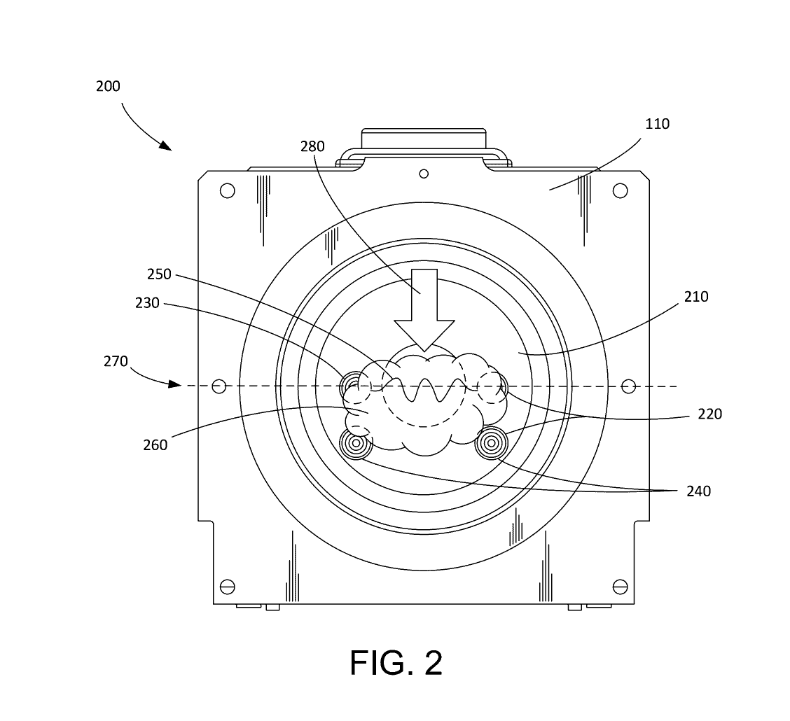

FIG. 1 illustrates a PECVD apparatus 110 with integrated magnet array components 100, according to one aspect of the present description. The chemical vapor deposition process, where a thin film layer is deposited onto a substrate, may occur within the PECVD apparatus 110. An array configured to affect a plasma 260 density (see FIG. 2) may be located adjacent to the PECVD apparatus 110. In some embodiments, the array may comprise a motor 170, a connector 160, a spindle 150, a motor plate 140, a magnet rotor plate 130, and a magnet 120.

FIG. 2 illustrates the PECVD apparatus components 200, according to one aspect of the present description. The PECVD apparatus 110 may comprise a deposition chamber 210 for depositing the thin film layer onto the substrate. The deposition chamber 210 may have a feed-through 220 for both a cathode 230 and an anode 240. In some embodiments, for example, a hot filament 250 electron source may run between the cathode 230 feed-through 220. During the deposition process, the cathode 230 and anode 240 may excite reactant gases in the deposition chamber 210 to create a plasma 260. A resulting chemical reaction may produce the thin film deposit on the substrate.

While the filament 250 may initially be aligned along a centerline axis 270, gravity 280 may pull the filament 250 down as the filament 250 ages. As such, the filament 250 may become asymmetrical or misaligned relative to the centerline axis 270, causing an asymmetric electron distribution. As a result, there may be a higher plasma 260 density located low in the source, leading to a thicker deposit towards the bottom of the substrate and a thinner deposit towards the top of the substrate.

Non-uniformity of the deposit can adversely affect the mechanical and recording performance of the media. For example, thinner film layer areas pose a greater risk for media corrosion and durability issues. The circumferential once-around thickness uniformity impacts the bit error rate performance due to head-media spacing variation. Furthermore, recording subsystem performance can be limited by bit error rate variation contributions from the media overcoat non-uniformity.

### Magnet Array

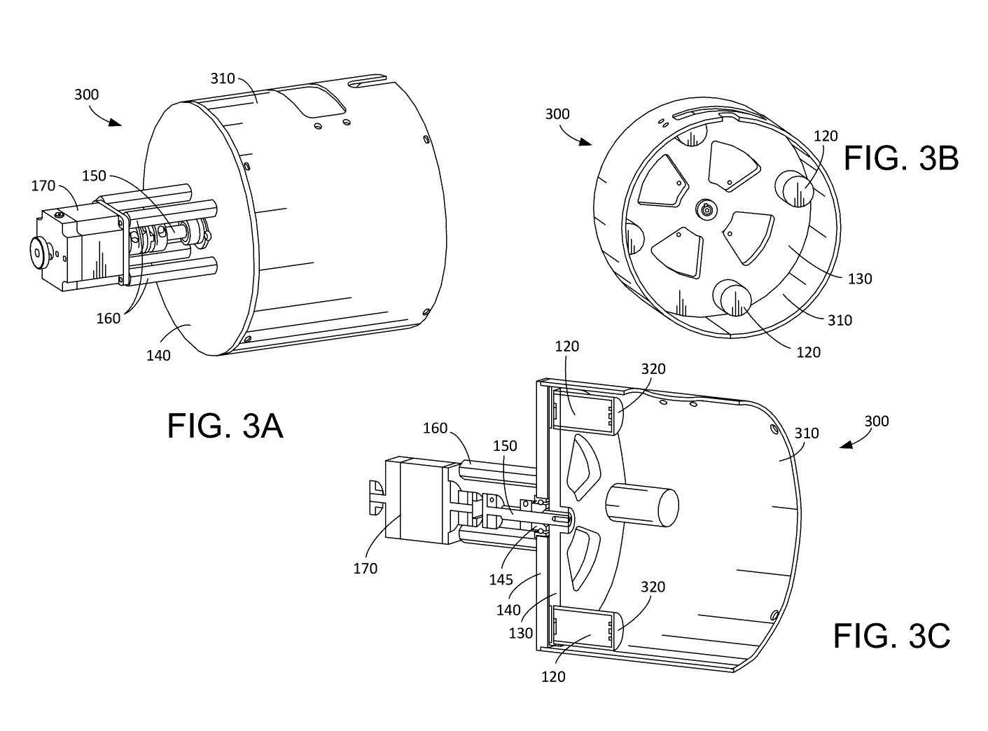

FIG. 3A illustrates a magnet array 300, according to one aspect of the present description. To compensate for the misaligned filament and prevent an uneven deposit of thin film layers, the magnet array 300 may be used to influence the plasma 260 within the deposition chamber 210. The magnet array 300 may be adjacently attached to the deposition chamber 210 through the use of screws or other attachment means. The magnet array 300 may be configured to create a deposition averaging effect during movement and increase thin film layer uniformity.

As shown in FIG. 3A, the magnet array 300 may comprise the motor 170, the connector 160, the spindle 150, the motor plate 140, the magnet rotor plate 130 (shown in FIG. 3B), the magnet 120 or multiple magnets 120, and a cover 310 surrounding the magnets 120. In some embodiments, for example, the motor plate 140 may be a circular shape and made of an aluminum material. In some embodiments, for example, the cover 310 surrounding the magnet 120 may be a cylindrical shape and made of an aluminum material. The motor 170 may rotate the magnet 120 in a circular pattern but may also move the magnet 120 closer to or away from the deposition chamber 210. In some embodiments, for example, the motor 170 may angle the magnet 120 at various degrees from the deposition chamber 210. The motor 170 may also vary the speed at which the magnet 120 moves at different times during the deposition process. It should be noted that any specific references to shapes and materials are for illustrative purposes only and are not intended to be limiting in scope.

FIG. 3B illustrates the magnet array 300, according to one aspect of the present description. As shown in FIG. 3B, the magnet 120 may be placed on or around the magnet rotor plate 130 designed to rotate the magnet 120. In some embodiments, for example, the magnet 120 may be stationary relative to the magnet rotor plate 130 during movement of the magnet array 300. In some embodiments, for example, the magnets 120 may be arranged asymmetrically to create an asymmetric field about the filament 250 that evens an asymmetric distribution of plasma 260 in the deposition chamber 210 during movement of the magnet array 300. The asymmetric field may be an asymmetric magnetic field caused by the magnets 120.

In some embodiments, for example, the magnets 120 may be arranged symmetrically to create an asymmetric field about the filament 250 that evens an asymmetric distribution of plasma 260 in the deposition chamber 210 during movement of the magnet array 300. When the magnets 120 are symmetrically arranged, magnets 120 of different strengths may be placed in certain locations on or around the magnet rotor plate 130 to create the desired asymmetric field about the filament 250. Similarly, when the magnets 120 are arranged symmetrically, magnets 120 of different polarities may also be used in certain location on or around the magnet rotor plate 130 to create the desired asymmetric field.

The magnets 120 may be located on the outer edge of the rotor plate 130, as depicted in FIG. 3B. However, the magnets may also be located towards the center of the rotor plate 130, or in any combination of locations on or around the rotor plate 130 to create the desired effect on distribution of plasma 260. In some embodiments, for example, the magnets 120 may be arranged along the radius, in concentric circles, or in any pattern on or around the rotor plate 130 to create an asymmetric field about the filament 250 that evens an asymmetric distribution of plasma 260 in the deposition chamber 210 during movement of the magnet array 300.

A single magnet rotor plate 130 or multiple magnet rotor plates 130 may be used to rotate the magnet 120. In some embodiments, for example, the magnet array 300 may comprise an even number of magnet rotor plates 130 or an odd number of magnet rotor plates 130. In some embodiments, for example, the magnet array 300 may comprise any number of magnet rotor plates 130 (e.g. ranging from 1 to 20). For example, the magnet rotor plate 130 count may be at least 20, 40, 65, 100 or more. In some embodiments, for example, the magnet rotor plate 130 may be made of an aluminum material. Furthermore, in some embodiments, the magnet 120 may be placed in a sleeve 320 (shown in FIG. 3C) adjacently connected to the magnet rotor plate 130 designed to insulate and hold the magnet 120. In some embodiments, for example, the sleeve 320 may be made of Teflon or other insulating materials. It should be noted that any specific references to number of magnets or materials are for illustrative purposes only and are not intended to be limiting in scope.

### Magnets

The magnet array 300 may comprise an even number of magnets 120 or an odd number of magnets 120. Any number of magnets 120 may be used. For example, the magnet count may range from 1 to 50, 50 to 100, 100 to 110, or 110 to 200. Further examples may include magnet counts of at least 5, 10, 15, 20, 25, 30, 35, 40, 45, or 50. Still further examples may include magnet counts of no more than 50, 45, 40, 35, 30, 25, 20, 15, 10, or 5. Combinations of the foregoing number of magnets 120 may also be used, including: at least 1 and no more than 20, at least 12 and no more than 82, at least 20 and no more than 90, at least 30 and no more than 40, or at least 50 and no more than 200. As previously stated, any specific references to number of magnets are for illustrative purposes only and are not intended to be limiting in scope.

The magnet 120 may have any close-formed shape. In some embodiments, for example, the magnet 120 may have a symmetric or an asymmetric shape. In some embodiments, for example, the magnet 120 may be shaped in the form of a cylinder, a square, a rectangle, a hexagon, a triangle, a diamond, a kidney bean, a heart, a star, or any other close-formed shape. It should be noted that any specific references to shapes are for illustrative purposes only and are not intended to be limiting in scope.

The magnet 120 may have any open-formed shape. In some embodiments, for example, the magnet 120 may have a symmetric or an asymmetric shape. For example, the magnet 120 may be shaped in the form of a spiral, an open ellipse, an open polygon, or any other open-formed shape. It should be noted that any specific references to shapes are for illustrative purposes only and are not intended to be limiting in scope.

The magnet 120 may also have any hollow shape. In some embodiments, for example, the magnet 120 may be shaped in the form of a hollow cylinder, a hollow square, a hollow rectangle, a hollow hexagon, a hollow triangle, a hollow diamond, a hollow kidney bean, a hollow heart, a hollow star, or any other hollow shapes. It should be noted that any specific references to shapes are for illustrative purposes only and are not intended to be limiting in scope.

The magnet 120 may be of any size. In some embodiments, for example, the magnet diameter may range from 0 to 50, 50 to 100, 100 to 120, or 120 to 200 centimeters (cm) long. Further examples may include magnet diameters of at least 10, 20, 30, 40, or 50 cm. Still further examples may include magnet diameters of no more than 100, 90, 80, 70, 60 or 50 cm. In some embodiments, for example, the magnet diameter may range from 1 to 100, 100 to 200, or 200 to 300 inches. It should be noted that any specific references to magnet diameter are for illustrative purposes only and are not intended to be limiting in scope.

The magnet 120 may also be of any strength. In some embodiments, for example, the maximum energy product in Mega Gauss Oersteds (MGOe) can range between 20 and 50. For example, the MGOe can range from 20 to 30, 30 to 40, or 40 to 50. Further examples may include MGOe measurements of less than 45, 25, or 15. Still further examples may include MGOe measurements of no more than 60, 30 or 20. It should be noted that any specific references to magnet strength are for illustrative purposes only and are not intended to be limiting in scope.

The magnets 120 may be arranged symmetrically or asymmetrically on the rotor plate 130 to create an asymmetric magnetic field designed to asymmetrically affect the distribution of plasma 260 inside the deposition chamber 210. In some embodiments, for example, the magnets 120 may be arranged asymmetrically so as to even an asymmetric distribution of plasma 260 and enable a more uniform deposition of thin film layers on the substrate. The magnets 120 may be located on the outer edge of the rotor plate 130, as depicted in FIG. 3B. However, the magnets may also be located towards the center of the rotor plate 130, or in any combination of locations on or around the rotor plate 130 to create the desired effect on the distribution of plasma 260. In some embodiments, for example, the magnets 120 may be arranged along the radius, in concentric circles, or in any pattern on or around the rotor plate 130 to create an asymmetric magnetic field designed to affect the distribution of plasma 260 inside the deposition chamber 210. It should be noted that any specific references to arrangements are for illustrative purposes only and are not intended to be limiting in scope.

In some embodiments, the magnets 120 may be arranged so that the same polarities face the deposition chamber 210 to create an asymmetric field about the filament 250 that evens an asymmetric distribution of plasma 260 during movement of the magnet array 300. For example, the magnets 120 may be arranged such that the south poles are closest to the deposition chamber 210. In some embodiments, for example, the magnets 120 may be arranged such that the north poles are closet to the deposition chamber 210. The magnets 120 may also be arranged so that a combination of north and south poles are closest to the deposition chamber 210, according to some embodiments. For example, the magnet array 300 may have one magnet 120 arranged with its south pole nearest the deposition chamber and another magnet 120 arranged with its north pole nearest the deposition chamber 210. In some embodiments, for example, any number of magnets 120 may be arranged with south poles nearest the deposition chamber. In some embodiments, the magnet 120 may be arranged so that the north and south poles are equidistant from the deposition chamber, or in any combination of the polarity arrangements to achieve the desired effect on the distribution of plasma 260 in the deposition chamber 210. It should be noted that any specific references to polarity arrangements are for illustrative purposes only and are not intended to be limiting in scope.

### Non-magnetic Weight

In some embodiments, a non-magnetic weight (not depicted), or multiple non-magnetic weights, may be used to counter balance a weight of the magnets 120 during rotation of the magnet array 300. In some embodiments, the non-magnetic weight may comprise stainless steel, but may comprise any material. In some embodiments, the non-magnetic weight may have approximately the same mass as the magnet 120 to balance the weight of the magnets 120 during rotation of the magnet array 300. In other embodiments, the non-magnetic weight may have a different mass than the magnet 120. When the non-magnetic weight has a different mass than the magnet 120, the non-magnetic weight may vary in number and location so as to counter balance the weight of the magnets 120 during rotation of the magnet array 300. For example, a magnet 120 may be counter balanced by two non-magnetic weights with half the mass of the magnet 120.

The non-magnetic weight may be arranged symmetrically or asymmetrically on the rotor plate 130 to balance the weight of the magnet 120 during rotation of the magnet array 300. The non-magnetic weight may be located on the outer edge of the rotor plate 130, towards the center of the rotor plate 130, or in any combination of locations on or around the rotor plate 130 to create the desired balancing effect. In some embodiments, for example, the non-magnetic weight may be arranged along the radius, in concentric circles, or in any pattern on or around the rotor plate 130. It should be noted that any specific references to arrangements are for illustrative purposes only and are not intended to be limiting in scope.

The non-magnetic weight may have the same shape as the magnet 120, or a different shape from the magnet 120. In some embodiments, any close-formed shape may be used. For example, the non-magnetic weight may be shaped in the form of a cylinder, a square, a rectangle, a hexagon, a triangle, a diamond, a kidney bean, a heart, a star, or any other close-formed shape. In other embodiments, any open-formed shape may be used. For example, the non-magnetic weight may be shaped in the form of a spiral, an open ellipse, an open polygon, or any other open-formed shape. In some embodiments, any hollow shape may be used. For example, the non-magnetic weight may be shaped in the form of a hollow cylinder, a hollow square, a hollow rectangle, a hollow hexagon, a hollow triangle, a hollow diamond, a hollow kidney bean, a hollow heart, a hollow star, or any other hollow shape. It should be noted that any specific references to shapes are for illustrative purposes only and are not intended to be limiting in scope.

The non-magnetic weight may have the same or different size as the magnet 120. For example, the diameter of the non-magnetic weight may range from 0 to 50, 50 to 100, 100 to 120, or 120 to 200 centimeters (cm) long. Further examples may include diameters of at least 10, 20, 30, 40, or 50 cm. Still further examples may include diameters of no more than 100, 90, 80, 70, 60 or 50 cm. In some embodiments, for example, the diameter may range from 1 to 100, 100 to 200, or 200 to 300 inches. It should be noted that any specific references to non-magnetic weight diameter are for illustrative purposes only and are not intended to be limiting in scope.

### Multiple Magnet Arrays

In some embodiments, multiple magnet arrays 300 may be used to create an asymmetric field about the filament 250 that evens an asymmetric distribution of plasma 260 in the deposition chamber 210 during movement of the magnet arrays 300. In some embodiments, for example, 1 to 10 magnet arrays 300 may be used to achieve a desired effect on the plasma 260. These magnet arrays 300 may be placed across from each other, adjacent to each other, above or below the deposition chamber 210, circumferentially around the deposition chamber 210, or in any combination of positions designed to yield the desired effect on the distribution of plasma 260. In some embodiments, for example, a magnet array 300 may be placed on either side of the deposition chamber 210 to influence the distribution of plasma 260 on either side of the substrate. It should be noted that any specific references to position of the magnet array are for illustrative purposes only and are not intended to be limiting in scope.

Each magnet array 300 of the multiple magnet arrays 300 may have the same number of magnet rotator plates 130, or a different number of magnet rotator plates 130 relative to each of the other magnet arrays 300. Each magnet array 300 of the multiple magnet arrays 300 may have the same number of magnets 120 or a different number of magnets 120 relative to each of the other magnet arrays 300. In some embodiments, each magnet array 300 of the multiple magnet arrays 300 may have the same magnet shape or a different magnet shape relative to each of the other magnet arrays 300. Each magnet array 300 of the multiple magnet arrays 300 may have the same magnet size or different magnet sizes relative to each of the other magnet arrays 300. Each magnet array 300 of the multiple magnet arrays 300 may have the same magnet strength or different magnet strengths relative to each of the other magnet arrays 300. Each magnet array 300 of the multiple magnet arrays 300 may have the same magnet arrangement on the magnet rotor plate 130 or different magnet arrangements on the magnet rotor plate 130 relative to each of the other magnet arrays 300. Each magnet array 300 of the multiple magnet arrays 300 may have the same magnet polarity orientation or a different magnet polarity orientation relative to each of the other magnet arrays 300.

Each magnet array 300 of the multiple magnet arrays 300 may have the same number of non-magnetic weights or different numbers of non-magnetic weights relative to each of the other magnet arrays 300. Each magnet array 300 of the multiple magnet arrays 300 may have the same shape of non-magnetic weights or different shapes of non-magnetic weights relative to each of the other magnet arrays 300. Each magnet array 300 of the multiple magnet arrays 300 may have the same sized non-magnetic weights or different sized non-magnetic weights relative to each of the other magnet arrays 300. Each magnet array 300 of the multiple magnet arrays 300 may have the same location of non-magnetic weights or different locations of non-magnetic weights relative to each of the other magnet arrays 300.

### Magnet Array Component Orientation

FIG. 3C illustrates a cross-sectional view of the magnet array 300, according to one aspect of the present description. The magnet array 300 may comprise the motor 170, the spindle 150, the motor plate 140, the magnet rotor plate 130, the magnet 120, the sleeve 320, and the cover 310 surrounding the magnets 120.

The motor 170 may be located adjacent to the magnets 120. The motor 170 may be connected to a motor plate 140 through any number of connectors 160. There may be an even number of connectors 160 or an odd number of connectors 160. For example, there may be a range of connectors 160 ranging from 1 to 10, 10 to 50, or 50 to 100. Further examples may include at least 2, 4, 6, 8, or 10 connectors 160. Still further examples may include no more than 200, 100, 80, 40, or 20 connectors 160. As such, the motor 170 may be held stationary relative to the motor plate 140 due to the connectors 160. It should be noted that any specific references to the number of connectors 160 are for illustrative purposes only and are not intended to be limiting in scope.

A spindle 150, or multiple spindles 150, may extend from the motor 170 towards a motor plate 140, pass through an opening 145 in the motor plate 140, and connect to the magnet rotor plate 130. Any number of spindles 150 may be used. A cover 310 may be connected to the motor plate 140 such that the cover 310 and the motor plate 140 are stationary relative to each other. The cover 310 may extend outward from the motor plate 140 and surround the circumference of the magnet rotor plate 130.

In some embodiments, the spindle 150 or the magnet rotor plate 130 may be configured for movement relative to the stationary cover 310 or stationary motor plate 140. For example, the spindle 150 and the stationary cover 310 may be configured for relative rotation. In some embodiments, for example, the magnet rotor plate 130 and the stationary motor plate 140 may be configured for relative rotation. In other embodiments, for example, the spindle 150 and the stationary motor plate 140 may be configured for relative rotation. In still other embodiments, for example, the magnet rotor plate 130 and the stationary cover 310 may be configured for relative rotation. Furthermore, the magnet 120 may be stationary relative to the magnet rotor plate 130. As such, the magnet 120 and the stationary cover 310 may be configured for relative rotation. In some embodiments, the sleeve 320 be stationary relative to the magnet rotor plate 130. As such, the sleeve 320 and the stationary cover 310 may be configured for relative rotation.

### Magnet Movement and Orientation

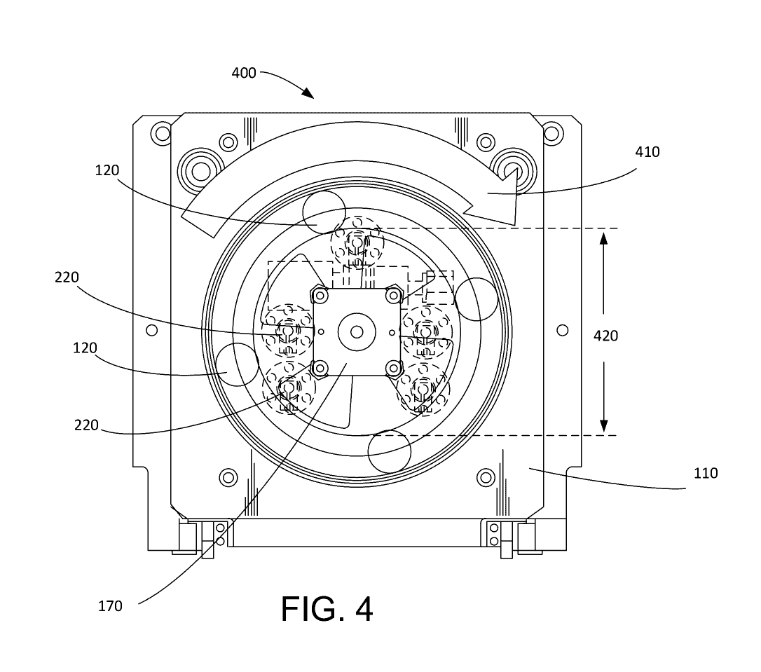

FIG. 4 illustrates a magnet array rotation 400 according to one aspect of the present description. The magnet array 300 may be configured to rotate the magnet 120 in a circular path 410 adjacent to the deposition chamber 210. The circular path 410 may be located outside a feed-through diameter 420 to better produce an averaging effect by creating a larger asymmetric field.

The feed-through diameter 420 may be any length. For example, the feed-through diameter 420 may range from less than 1 centimeter, to several centimeters, to tens of centimeters long. In some embodiments, for example, the feed-through diameter 420 may range from 1 to 100, 100 to 150, or 150 to 180 cm in length. Further examples may include a feed-through diameter 420 of at least 10, 30, 50, 70, or 90 cm in length. Still further examples may include a feed-through diameter 420 of no more than 100, 80, 60, 40, 20, or 10 cm in length. In other embodiments, the feed-through diameter 420 may range from inches, to several inches, to tens of inches long. For example, the feed-through diameter 420 may range from 1 to 20, 20 to 80, or 80 to 200 inches in length. Further examples may include a feed-through diameter 420 of at least 10, 20, 30, 40, 50, 60, 70, 80, 90, or 100 inches in length. Still further examples may include a feed-through diameter 420 of no more than 200, 150, 110, 50, or 20 inches in length. It should be noted that any specific references to length are for illustrative purposes only and are not intended to be limiting in scope.

The movement of the magnets 120 may vary in direction, speed, or angle to affect the distribution of plasma 260 in the deposition chamber 210. In some embodiments, for example, the magnets 120 may be rotated in either a clockwise or counter-clockwise fashion. In some embodiments, for example, the rotation may alternate from clockwise to counter-clockwise, or from counter-clockwise to clockwise to create the desired effect on the plasma 260 within the deposition chamber 210. It should be noted that any specific references to movement direction are for illustrative purposes only and are not intended to be limiting in scope. For example, in some embodiments, the magnets 120 may be moved up and down, from side to side, from front to back, in diagonal directions, around, or in direction or in any combinations thereof.

Furthermore, the speed of rotation may directly influence deposition uniformity. The averaging effect on deposition may be increased with an increase in rotational speed. As such, the averaging effect on deposition may be decreased with a decrease in rotational speed. In some embodiments, any range of rotational speeds may be used. For example, the rotational speed may vary from 0 rotations per minute (RPM) to 1000 RPM. Further examples may include rotation speeds of less than 1, 20, 70, 300, or 450 RPM. Still further examples may include rotational speeds of no more than 2000 RPM. In some embodiments, the magnets 120 may have rotational speeds of less than 100, 200, 300, 400, 500, 600, 700, 800, 900, or 1000 RPM. Furthermore, any combination of speeds may also be used. In some embodiments, for example, the magnets 120 may have a rotational speed of between 0 and 600 RPM, between 100 and 700 RPM, between 200 and 800 RPM, between 300 and 900 RPM, or between 400 and 2000 RPM. It should be noted that any specific references to speed are for illustrative purposes only and are not intended to be limiting in scope.

Any range of orientation angles may be used to angle the magnets 120 from the deposition chamber 210 to create an asymmetric field in the deposition chamber designed to affect an asymmetric distribution of plasma 260. The magnets 120 may have an orientation angle of at least 0°, 20°, 45°, 50°, 60°, 65°, 70°, or 180°. In some embodiments, for example, the magnets may be oriented at an angle of no more than 180°, 165°, 50°, 30°, 10°, 5°, or 0°. Any combination of angles may also be used to describe the angle at which the magnets 120 may be oriented. In some embodiments, for example, the magnets 120 may be oriented at an angle of at least 0° and no more than 90°, such as at least 0° and no more than 45° or at least 45° and no more than 360°. Moreover, any orientation angle may be used for different magnets. In some embodiments, for example, one magnet may be oriented at 0° while another is angled at 90°. It should be noted that any specific references to orientation angles are for illustrative purposes only and are not intended to be limiting in scope.

The orientation angles may be altered during rotation of the magnet array 300 to achieve the desired effect on the distribution of plasma 260. Any combination of orientation angle adjustments may be used. For example, the magnet 120 may start at an orientation angle of 0° but may be adjusted to an angle of, for example, 5°, 25°, 80°, or 150° during rotation. Further examples may include starting the magnet 120 at an orientation angle of 50° and adjusting the orientation angle to, for example, 0°, 100°, 120°, or 180° during rotation. In some embodiments, the orientation angle may be adjusted by less than 1°, 5°, 90°, or 180° during rotation. In other embodiments, the orientation angle may be adjusted by no more than 360°, 220°, 130°, or 70° during rotation. It should be noted that any specific references to orientation angles and adjustments thereof are for illustrative purposes only and are not intended to be limiting in scope.

In some embodiments, the magnets 120 may be rotating or stationary relative to the other magnets 120 in the magnet array, or relative to the deposition chamber 210. For example, one magnet 120 may be stationary relative to the deposition chamber 210 during rotation while another magnet 120 may be rotating relative to the deposition chamber 210. Further examples may include a number of magnets 120 stationary relative to a number of other magnets 120 that may be rotating.

### Multiple Magnet Arrays' Movement and Orientation

If multiple magnet arrays 300 are used, each magnet array 300 of the multiple magnet arrays 300 may be configured to move the magnets 120 in the same direction or a different direction as each of the other magnet arrays 300. In some embodiments, for example, multiple magnet arrays 300 may rotate the magnets 120 in a clockwise direction. In some embodiments, for example, multiple magnet arrays 300 may rotate the magnets 120 in a counter-clockwise direction. Combinations of the forgoing rotational directions may also be used. In some embodiments, for example, one magnet array 300 may rotate the magnets 120 in a clockwise direction while another magnet array 300 may rotate the magnets 120 in a counter-clockwise direction. In some embodiments, for example, a number of magnet arrays 300 may rotate the magnets 120 in a clockwise direction while a number of other magnet arrays 300 may rotate the magnets 120 in a counter-clockwise direction.

Each magnet array 300 of the multiple magnet arrays 300 may be configured to rotate the magnets 120 at the same speed or at different speeds. In some embodiments for example, one magnet array 300 of the multiple magnet arrays 300 may rotate at a faster speed than another magnet array 300. In some embodiments, for example, one magnet array 300 of the multiple magnet arrays 300 may rotate at a slower speed than another magnet array 300. In some embodiments, one or multiple magnet arrays 300 may increase rotational speed or decrease rotational speed during the deposition process to achieve the desired averaging effect on the plasma 260.

Each magnet array 300 of the multiple magnet arrays 300 may be rotating or stationary relative to each of the other magnet arrays 300. In some embodiments, all the magnet arrays 300 may be rotating relative to the deposition chamber 210. In other embodiments, some magnet arrays 300 may be rotating relative to the deposition chamber 210 while other magnet arrays 300 may be stationary relative to the deposition chamber 210. In still other embodiments, all the magnet arrays 300 may be stationary relative to the deposition chamber 210.

In some embodiments, two or more magnet arrays 300 may be arranged on either side of the deposition chamber 210 with their magnets 120 facing each other. In some embodiments, for example, the magnets 120 of one magnet array 300 may have synchronous or asynchronous rotations with the magnets 120 of the other magnet arrays 300. In some embodiments, for example, the magnets 120 of one magnet array 300 may be aligned with the magnets 120 of another magnet array 300 during rotation. In some embodiments, for example, the magnets 120 of one magnet array 300 may be non-aligned with the magnets 120 of another magnet array 300 during rotation.

### Feedback System

The magnet array 300 may operate in conjunction with a feedback system. In some embodiments, for example, the feedback system may be configured to identify a misaligned filament 250 in comparison to a centerline axis 270. In some embodiments, the feedback system may be configured to identify an uneven distribution of plasma 260. In some embodiments, the feedback system may be configured to identify an uneven deposition of thin film on a substrate. The feedback system may then gather information relevant to adjusting a misaligned filament, an uneven plasma distribution or an uneven deposition of thin film on a substrate. The feedback system may then select and activate the magnet arrays 300 to create an asymmetric field about the filament 250 configured to even an asymmetric distribution of plasma 260 in the deposition chamber 210 during movement of the magnet arrays 300. In some embodiments, the feedback system may be automated to control the speed, direction, and angle of movement of the magnet arrays 300. In some embodiments, the feedback system may be automated to select which magnet arrays 300 to activate in order to optimize the effect of the asymmetric field on the distribution of plasma 260. In some embodiments, the feedback system may comprise a computer. In some embodiments, the feedback system may comprise software.

### PECVD Apparatus with Integrated Magnet Array

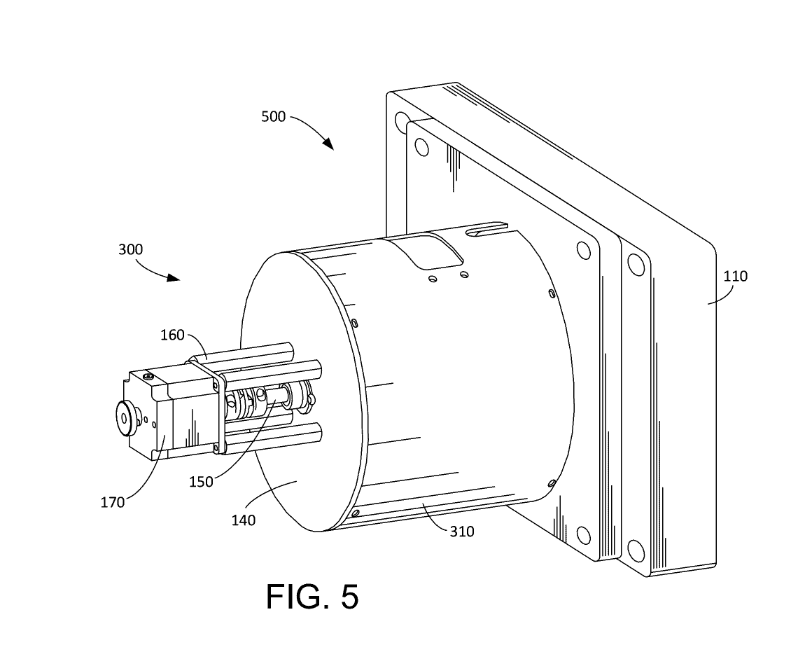

FIG. 5 illustrates the PECVD apparatus 110 with an integrated magnet array 500 according to one aspect of the present description. The PECVD apparatus 110 may comprise the deposition chamber 210 for depositing a thin film layer onto a substrate. The deposition chamber 210 may have the feed-through 220 for both the cathode 230 and the anode 240. In some embodiments, for example, the hot filament 250 electron source may run between the cathode 230 feed-through 220. During the deposition process, the cathode 230 and anode 240 may excite reactant gases in the deposition chamber 210 to create the plasma 260. The resulting chemical reaction may produce the thin film deposit on the substrate. The integrated magnet array 500 configured to affect a plasma 260 density in the deposition chamber 210 may be located adjacent to the PECVD apparatus 110. The integrated magnet array 500 may comprise the motor 170, connector 160, spindle 150, motor plate 140, magnet rotor plate 130, magnet 120 or multiple magnets 120, and cover 310 surrounding the magnets 120.

### Effects of Rotating Magnets on Thin Film Thickness

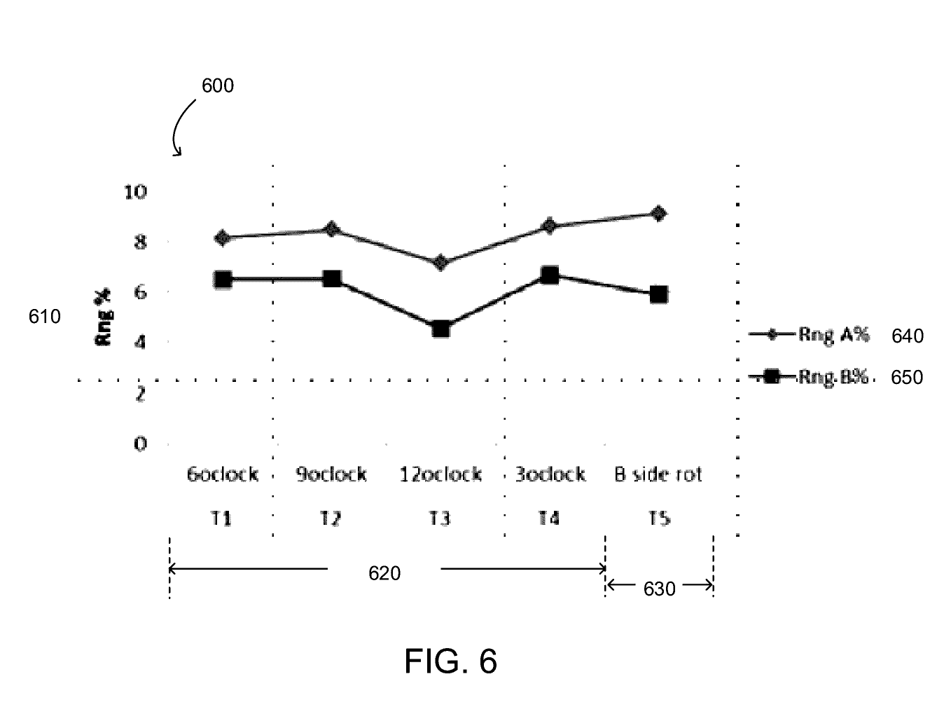

FIG. 6 illustrates a graphical comparison 600 of static and rotating range percentages of substrate sides according to one aspect of the present description. The vertical axis illustrates a range percentage 610, which measures thin film thickness uniformity. The range percentage 610 is calculated by taking the difference between a maximum thickness and a minimum thickness of the thin film in angstroms, as measured based on optical constants n and k, dividing by a mean thickness, and multiplying by 100. The range percentage 610 is calculated for both Side A 640 of the substrate and for Side B 650 of the substrate.

The horizontal axis illustrates various test instances of static (i.e. non-rotating) magnet arrays 620 and a rotating (i.e. non-static) magnet array 630. In all test instances, the static magnet arrays 620 and the rotating magnet array 630 are located adjacent to Side B 650 of the substrate while no magnet arrays 620, 630 are located adjacent to Side A 640 of the substrate. In one instance, the static magnet array 620 has a magnet 120 placed at the 6 o'clock position. In one instance, the static magnet array 620 has a magnet 120 placed at the 9 o'clock position. In one instance, the static magnet array 620 has a magnet 120 placed at the 12 o'clock position. In one instance, the static magnet array 620 has a magnet 120 placed at the 3 o'clock position. In the instance of a rotating magnet array 630, the magnet 120 adjacent to Side B 650 of the substrate is rotated.

The graph indicates that the range percentage 610 of Side A 640 and Side B 650 trend together with static magnet array 620 positions. However, when rotating the magnet 120 adjacent to Side B 650, the range percentage 610 between Side A 640 and Side B 650 diverges, with Side B showing improvement in the range percentage 610. As such, rotating the magnet array 630 may result in a deposition averaging effect and increased thin film layer uniformity compared to keeping the magnet array 620 stationary.

In view of the foregoing, provided herein is a magnet array configured to create an asymmetric field designed to influence a plasma distribution in a deposition chamber of a PECVD apparatus.

As such, provided herein is an apparatus comprising a deposition chamber, a cathode in the deposition chamber, wherein the cathode comprises a filament, a magnet adjacent to a deposition chamber, a magnet holder connected to the magnet, and a motor configured to create an asymmetric field about the filament through movement of the magnet. For example, FIGS. 1 and 2 illustrate a PECVD apparatus with a deposition chamber containing a hot filament cathode. FIG. 1-5 further illustrate a magnet, a magnet holder, and a motor adjacent to the deposition chamber, where the motor is configured to rotate the magnet and create an asymmetric field about the filament. In some embodiments, the magnet holder comprises a sleeve, as may be seen in FIG. 3C, for example. In some embodiments, the magnet holder comprises a first plate, such as the magnet rotor plate seen in FIG. 1, 3B, and 3C. In some embodiments, the apparatus further comprises an enclosure surrounding the magnet. For example, FIG. 3A-3C and 5 illustrate a cover surrounding the magnet. In some embodiments, the apparatus further comprises a second plate adjacent to the enclosure. For example, FIG. 1, 3A, 3C, and 5 illustrate a motor plate adjacent to the cover. In some embodiments, the magnet holder and the second plate are configured for relative rotation, as may be seen in FIG. 3C. In some embodiments, the filament is asymmetrical relative to a centerline axis, as depicted in FIG. 2, for example.

Also provided herein is an apparatus comprising a deposition chamber including a cathode, and a means for creating an asymmetric field about the cathode. For example, FIGS. 1 and 2 illustrate a PECVD apparatus with a deposition chamber containing a hot filament cathode. FIG. 1, 3A-3C, and 5 further illustrate a means for creating an asymmetric field about the cathode. In some embodiments, the apparatus further comprises a magnet array adjacent to the deposition chamber comprising a magnet, as illustrated in FIG. 1, 3A-3C, and 5. In some embodiments, the means for creating an asymmetric field about the cathode includes a motor configured to move the magnet, as illustrated in FIG. 1, 3A-3C, 4, and 5. In some embodiments, the means for creating an asymmetric field about the cathode includes multiple arrays. For example, multiple magnet arrays, as illustrated in FIG. 3A-3C, may be placed adjacent to the deposition chamber to create an asymmetric field about the cathode. In some embodiments, the means for creating an asymmetric field about the cathode includes multiple magnets and non-magnetic weights. Multiple magnets may be seen, for example, in FIG. 1, 3B, 3C, and 4. In some embodiments, the magnet is stationary relative to a plate during movement of the magnet array. For example, FIG. 1, 3B, and 3C illustrate the magnet connected to the magnet rotor plate so that the magnet remains stationary relative to the magnet rotor plate during movement. In some embodiments, the apparatus further comprises a non-magnet weight positioned to counter balance the magnet. For example, the arrangement illustrated in FIG. 1, 3B, 3C, and 4 may comprise non-magnetic weights positioned to counter balance the magnet. In some embodiments, the magnet is positioned outside a feed-through diameter, as illustrated in FIG. 4.

Also provided herein is a method of positioning a magnet in a first position relative to a deposition chamber and moving the magnet to a second position relative to the first position. For example, FIG. 4 illustrates movement of the magnet in a circular path. In some embodiments, moving the magnet to the second position creates an asymmetric magnetic field about a filament in the deposition chamber. For example, FIG. 2 illustrates the filament in the deposition chamber while FIG. 4 illustrates the movement of the magnet to create an asymmetric magnetic field about the filament. In some embodiments, moving the magnet to the second position comprises rotating the magnet, as illustrated in FIG. 4. In some embodiments, moving the magnet to the second position comprises rotating a plate adjacent to the magnet. For example, FIG. 1, 3B, and 3C illustrate a magnet attached to a magnet rotor plate that is configured to rotate. In some embodiments, moving the magnet to the second position affects an asymmetric plasma distribution, as illustrated in FIG. 2. In some embodiments, the method further comprises operating a motor adjacent to the magnet. For example, FIG. 1, 3A, 3C, 4, and 5 illustrate the motor. In some embodiments, the method further comprises positioning a non-magnetic weight adjacent to the magnets.

While some particular embodiments have been illustrated and/or described herein, and while the particular embodiments have been illustrated and/or described in some detail, it is not the intention of the applicant(s) for the particular embodiments to limit the scope of the concepts presented herein. Additional adaptations and/or modifications may readily appear to persons having ordinary skill in the art and, in broader aspects, these adaptations and/or modifications may be encompassed as well. Accordingly, departures may be made from the particular embodiments illustrated and/or described herein without departing from the scope of the concepts provided herein. The implementations provided herein and other implementations are within the scope of the following claims.

What is claimed is:

1. An apparatus comprising:
a deposition chamber;
a cathode in the deposition chamber,
wherein the cathode comprises a filament;
a magnet adjacent to a deposition chamber;
a magnet holder connected to the magnet; and
a motor configured to create an asymmetric field about the filament through movement of the magnet.

2. The apparatus of claim 1,
wherein the magnet holder comprises a sleeve.

3. The apparatus of claim 1,
wherein the magnet holder comprises a first plate.

4. The apparatus of claim 1, further comprising:
an enclosure surrounding the magnet.

5. The apparatus of claim 4, further comprising:
a second plate adjacent to the enclosure.

6. The apparatus of claim 5,
wherein the magnet holder and the second plate are configured for relative rotation.

7. The apparatus of claim 1,
wherein the filament is asymmetrical relative to a centerline axis.

8. An apparatus comprising:
a deposition chamber including a cathode; and
a means for creating an asymmetric field about the cathode.

9. The apparatus of claim 8, further comprising:
a magnet array adjacent to the deposition chamber comprising a magnet,
wherein the means for creating an asymmetric field about the cathode includes a motor configured to move the magnet.

10. The apparatus of claim 8,
wherein the means for creating the asymmetric field about the cathode includes multiple magnet arrays.

11. The apparatus of claim 8,
wherein the means for creating the asymmetric field about the cathode includes multiple magnets and non-magnetic weights.

12. The apparatus of claim 9,
wherein the magnet is stationary relative to a plate during movement of the magnet array.

13. The apparatus of claim 9, further comprising:
a non-magnetic weight positioned to counter balance the magnet.

14. The apparatus of claim 9,
wherein the magnet is positioned outside a feed-through diameter.

15. A method comprising:
positioning a magnet in a first position relative to a deposition chamber; and
moving the magnet to a second position relative to the first position,
wherein the moving the magnet to the second position creates an asymmetric magnetic field about a filament in the deposition chamber.

16. The method of claim 15,
wherein moving the magnet to the second position comprises rotating the magnet.

17. The method of claim 15,
wherein moving the magnet to the second position comprises rotating a plate adjacent to the magnet.

18. The method of claim 15,
wherein moving the magnet to the second position affects an asymmetric plasma distribution.

19. The method of claim 15, further comprising:
operating a motor adjacent to the magnet.

20. The method of claim 15, further comprising:
positioning a non-magnetic weight adjacent to the magnet.
